(19) United States
(12) Patent Application Publication
(10) Pub. No.: US 2026/0029578 A1
(43) Pub. Date: Jan. 29, 2026

(54) CRYOGENIC CHIP-ON-CHIP ASSEMBLIES WITH THERMAL ISOLATION STRUCTURES AND METHODS OF FORMING THEREOF

(71) Applicant: PsiQuantum Corp., Palo Alto, CA (US)

(72) Inventors: Alexey VERT, Clifton Park, NY (US); Vimal KAMINENI, Mechanicville, NY (US); Himani KAMINENI, Mechanicville, NY (US)

(21) Appl. No.: 18/997,137

(22) PCT Filed: Jul. 18, 2023
(86) PCT No.: PCT/US2023/028078

§ 371 Date: Jan. 20, 2025

Related U.S. Application Data
(60) Provisional application No. 63/390,369, filed on Jul. 19, 2022.

(51) Int. Cl. G02B 6/13; H01L 25/16

(52) U.S. Cl. CPC G02B 6/13; H01L 25/167

(57) ABSTRACT

A hybrid electronic-photonic package includes a photonic die containing photonic components, an electronic die bonded to the photonic die, and at least one of a cavity and an underfill material having a lower thermal conductivity than materials of the photonic die and the electronic die located between the photonic die and the electronic die.

### TECHNICAL FIELD

Embodiments herein relate generally to cryogenic photonic and electronic chip assemblies used for quantum computing (QC) applications, and more specifically to thermal isolation structures used in such assemblies and methods of forming thereof.

### BACKGROUND

A cryostat is a device that is used to maintain cryogenic temperatures (e.g., 120° K or less) for objects or materials located within the cryostat. Cryostats have been used for a number of applications in which cryogenic temperatures are desirable and/or necessary. For example, many types of quantum computing (QC) systems require quantum processing operations to be performed at extremely low temperatures. A cryostat may be used to house components of the QC system used to perform quantum processing operations such that these components may be maintained within a specified cryogenic temperature range.

### SUMMARY

According to one embodiment, a hybrid electronic-photonic package includes a photonic die containing photonic components, an electronic die bonded to the photonic die; and at least one of a cavity and an underfill material having a lower thermal conductivity than materials of the photonic die and the electronic die located between the photonic die and the electronic die.

According to another embodiment a method of making a hybrid electronic-photonic package comprises providing a photonic die comprising photonic components, providing an electronic die, and bonding the electronic die to the photonic die such that at least one of a cavity and an underfill material having a lower thermal conductivity than materials of the photonic die and the electronic die is located between the photonic die and the electronic die.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the Figures.

FIG. 1A is a simplified schematic diagram illustrating an optical switch, according to some embodiments.

FIG. 1B is an illustration of a user interfacing with a hybrid quantum computing device, according to some embodiments.

FIG. 2A is a vertical cross-sectional view of a hybrid electronic-photonic package including a cryo-die and a secondary die, according to various embodiments.

FIG. 2B is a vertical cross-sectional view of a further hybrid electronic-photonic package including a cryo-die and a secondary die, according to various embodiments.

FIG. 2C is a vertical cross-sectional view of a further hybrid electronic-photonic package including a cryo-die and a secondary die, according to various embodiments.

FIG. 3A is a vertical cross-sectional view of a cryo-die having blocking features prior to forming the underfill material, according to various embodiments.

FIG. 3B is a top view of the cryo-die of FIG. 3A after forming the underfill material, according to various embodiments.

FIG. 4A is a vertical cross-sectional view of a cryo-die having blocking features formed as a continuous boundary prior to forming the underfill material, according to various embodiments.

FIG. 4B is a top view of the cryo-die of FIG. 4A after forming the underfill material, according to various embodiments.

FIG. 5A is a vertical cross-sectional view of a further cryo-die having blocking features formed as a continuous trench prior to forming the underfill material, according to various embodiments.

FIG. 5B is a top view of the cryo-die of FIG. 5A after forming the underfill material, according to various embodiments.

While the features described herein may be susceptible to various modifications and alternative forms, specific embodiments thereof are shown by way of example in the drawings and are herein described in detail. It should be understood, however, that the drawings and detailed description thereto are not intended to be limiting to the particular form disclosed, but on the contrary, the intention is to cover all modifications, equivalents and alternatives falling within the spirit and scope of the subject matter as defined by the appended claims.

### DETAILED DESCRIPTION

Reference will now be made in detail to embodiments, examples of which are illustrated in the accompanying drawings. In the following detailed description, numerous specific details are set forth to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

It will also be understood that, although the terms first, second, etc. are, in some instances, used herein to describe various elements, these elements should not be limited by these terms. These terms are used only to distinguish one element from another. For example, a first electrode layer could be termed a second electrode layer, and, similarly, a second electrode layer could be termed a first electrode layer, without departing from the scope of the various described embodiments. The first electrode layer and the second electrode layer are both electrode layers, but they are not the same electrode layer.

The following description, for purpose of explanation, is described with reference to specific embodiments. However, the illustrative discussions that follow are not intended to be exhaustive or to limit the scope of the claims to the precise forms disclosed. Many modifications and variations are possible in view of the above teachings. The embodiments were chosen to best explain the principles underlying the claims and their practical applications, to thereby enable others skilled in the art to best use the embodiments with various modifications as are suited to the particular uses contemplated.

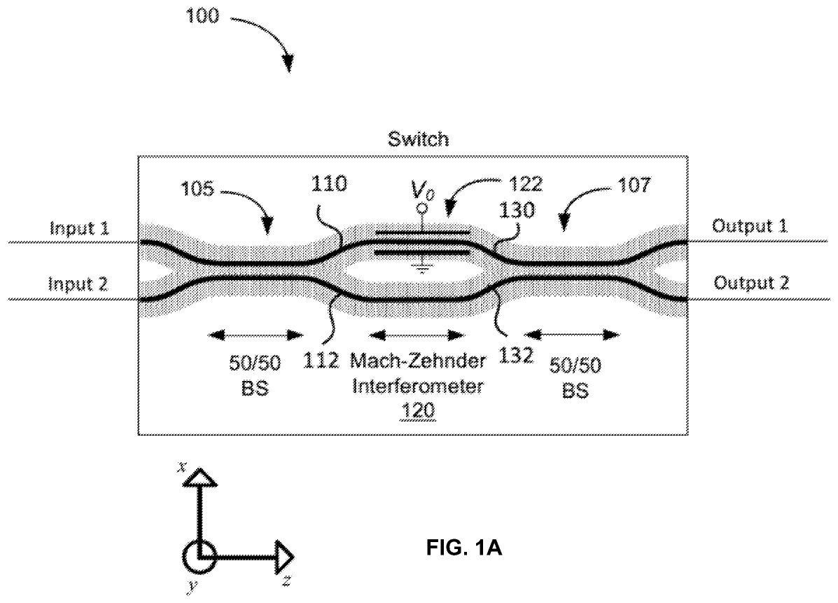

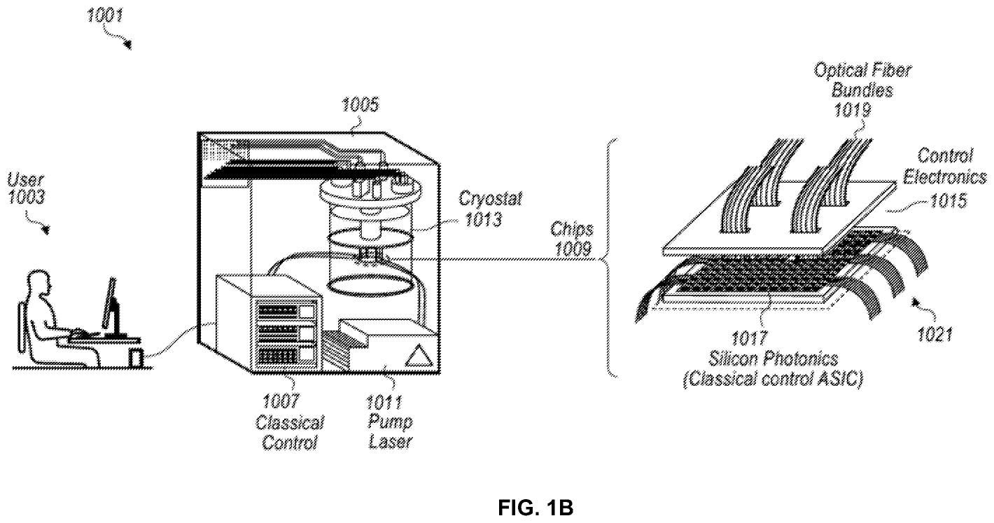

FIG. 1A is a simplified schematic diagram illustrating an optical switch according to an embodiment of this disclosure. Referring to FIG. 1A, switch 100 includes two inputs: Input 1 and Input 2 as well as two outputs: Output 1 and Output 2. As an example, the inputs and outputs of switch 100 can be implemented as optical waveguides operable to support single mode or multimode optical beams. As an example, switch 100 can be implemented as a Mach-Zehnder interferometer integrated with a set of 50/50 beam splitters 105 and 107, respectively. As illustrated in FIG. 1A, Input 1 and Input 2 are optically coupled to a first 50/50 beam splitter 105, also referred to as a directional coupler, which receives light from the Input 1 or Input 2 and, through evanescent coupling in the 50/50 beam splitter, directs 50% of the input light from Input 1 into waveguide 110 and 50% of the input light from Input 1 into waveguide 112. Concurrently, first 50/50 beam splitter 105 directs 50% of the input light from Input 2 into waveguide 110 and 50% of the input light from Input 2 into waveguide 112. Considering only input light from Input 1, the input light is split evenly between waveguides 110 and 112.

Mach-Zehnder interferometer 120 includes phase adjustment section 122. Voltage V₀ can be applied across the waveguide in phase adjustment section 122 such that it can have an index of refraction in phase adjustment section 122 that is controllably varied. Because light in waveguides 110 and 112 still have a well-defined phase relationship (e.g., they may be in-phase, 180° out-of-phase, etc.) after propagation through the first 50/50 beam splitter 105, phase adjustment in phase adjustment section 122 can introduce a predetermined phase difference between the light propagating in waveguides 130 and 132. As will be evident to one of skill in the art, the phase relationship between the light propagating in waveguides 130 and 132 can result in output light being present at Output 1 (e.g., light beams are in-phase) or Output 2 (e.g., light beams are out of phase), thereby providing switch functionality as light is directed to Output 1 or Output 2 as a function of the voltage V₀ applied at the phase adjustments section 122. Although a single active arm is illustrated in FIG. 1A, it will be appreciated that both arms of the Mach-Zehnder interferometer can include phase adjustment sections.

As illustrated in FIG. 1A, electro-optic switch technologies, in comparison to all-optical switch technologies, utilize the application of the electrical bias (e.g., V₀ in FIG. 1A) across the active region of the switch to produce optical variation. The electric field and/or current that results from application of this voltage bias results in changes in one or more optical properties of the active region, such as the index of refraction or absorbance.

Although a Mach-Zehnder interferometer implementation is illustrated in FIG. 1A, embodiments of this disclosure are not limited to this particular switch architecture and other phase adjustment devices are included within the scope of this disclosure, including ring resonator designs, Mach-Zehnder modulators, generalized Mach-Zehnder modulators, and the like. One of ordinary skill in the art would recognize many variations, modifications, and alternatives.

In some embodiments, the optical phase shifter devices described herein may be utilized within a quantum computing system such as the hybrid quantum computing system shown in FIG. 1B. Alternatively, these optical phase shifter devices may be used in other types of optical systems. For example, other computational, communication, and/or technological systems may utilize photonic phase shifters to direct optical signals (e.g., single photons or continuous wave (CW) optical signals) within a system or network, and phase shifter architectures described herein may be used within these systems, in various embodiments.

FIG. 1B is a simplified system diagram illustrating incorporation of an electro-optic switch with a prior art cryostat into a hybrid quantum computing system, according to some embodiments. In order to operate at low temperatures, for example liquid helium temperatures, embodiments of this disclosure integrate the electro-optic switches discussed herein (e.g., see FIG. 1A) into a system that includes cooling systems. Thus, embodiments of this disclosure provide an optical phase shifter that may be used within a hybrid computing system of the type illustrated in FIG. 1B. The hybrid computing system 1001 includes a user interface device 1003 that is communicatively coupled to a hybrid quantum computing (QC) sub-system 1005. The user interface device 1003 may be any type of user interface device, for example, a terminal including a display, keyboard, mouse, touchscreen, and the like. In addition, the user interface device may itself be a computer such as a personal computer (PC), laptop, tablet computer, etc.

In some embodiments, the user interface device 1003 provides an interface with which a user can interact with the hybrid QC subsystem 1005. For example, the user interface device 1003 may run software, such as a text editor, an interactive development environment (IDE), command prompt, graphical user interface, and the like so that the user can program, or otherwise interact with, the QC subsystem to run one or more quantum algorithms. In other embodiments, the QC subsystem 1005 may be pre-programmed and the user interface device 1003 may simply be an interface where a user can initiate a quantum computation, monitor the progress, and receive results from the hybrid QC subsystem 1005. Hybrid QC subsystem 1005 may further include a classical computing system 1007 coupled to one or more quantum computing chips 1009. In some examples, the classical computing system 1007 and the quantum computing chip 1009 can be coupled to other electronic components, e.g., pulsed pump lasers 1011, microwave oscillators, power supplies, networking hardware, etc.

The quantum computing chips 1009 may be housed within a cryostat, for example, cryostat 1013. In some embodiments, each of the quantum computing chips 1009 can include one or more constituent chips, e.g., hybrid electronic chip 1015 and integrated photonics chip 1017. The photonics chip 1017 may include the interferometer 100 shown in FIG. 1A. Signals can be routed on-and off-chip any number of ways, e.g., via optical interconnects (e.g., optical fiber bundles) 1019 and via other electronic interconnects 1021.

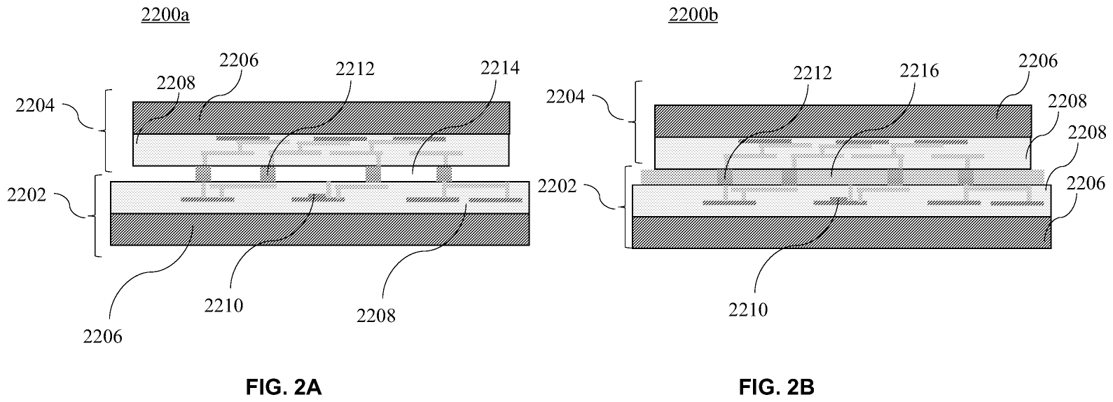

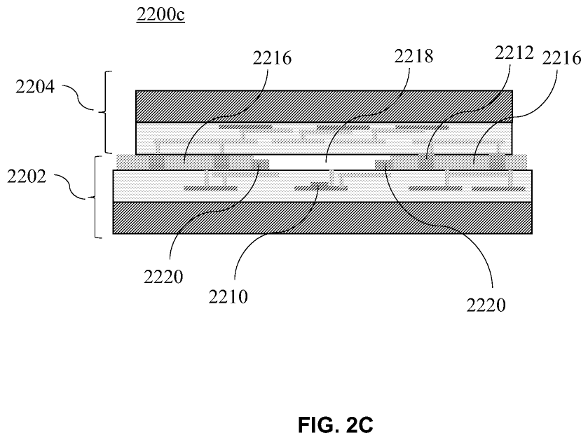

FIG. 2A is a vertical cross-sectional view of a first hybrid electronic-photonic package 2200a including a cryo-die 2202 and a secondary die 2204, and FIG. 2B is a vertical cross-sectional view of a second hybrid electronic-photonic package 2200b including a cryo-die 2202 and a secondary die 2204, according to various embodiments. In one embodiment, each package 2200a or 2200b may comprise one or more quantum computing chips 1009 described above with respect to FIG. 1B. Flip-chip or chip-on-chip (also chip-on-wafer) techniques may be used to form the first hybrid electronic-photonic package 2200a and second hybrid electronic-photonic package 2200b. Quantum computing systems operating at cryogenic temperatures (e.g., 10K and below), such as systems 2001 described above (e.g., see FIG. 1B and related description) may include two chips co-packaged in close proximity to one another such as the first hybrid electronic-photonic package 2200a or the second hybrid electronic-photonic package 2200b shown in FIGS. 2A and 2B. Each chip may contain one or more dies in a package. The cryo-die 2202 may be configured to perform quantum computing operations and may be part of the photonic chip (e.g., the photonic chip 1017 in FIG. 1B) or may be part of a hybrid electronic-photonic chip including electronic and photonic circuits. The secondary die 2204 may be part of the electronic chip (e.g., the electronic chip 1015 in FIG. 1B) or may be part of a hybrid electronic-photonic chip.

One of the chips (e.g., the chip containing the cryo-die 2202) may require strict temperature control to perform quantum computations. For example, the cryo-die 2202 may be mounted directly or indirectly to a liquid helium chamber to maintain its temperature at 4.2K or below. For example, the cryo-die 2202 may be indirectly mounted to an outer surface of the liquid helium chamber using an interposer.

The other chip (e.g., the secondary die 2204) may be held at a higher temperature and may provide control functions. For example, the secondary die 2204 may include classical semiconductor and/or other solid state devices (e.g., transistors, resistors, capacitors, etc.) and serve as a readout interface that may perform classical computations and data processing. The operations performed by the secondary die 2204 may generate heat that may cause the cryo-die 2202 to malfunction if the cryo-die 2202 is not sufficiently shielded from the generated heat. As such, thermal isolation between the secondary die 2204 and the cryo-die 2202 is desired for optimum operation of the system. As shown, each of the secondary die 2204 and a cryo-die 2202 may include a first portion 2206 and a second portion 2208. The first portion 2206 may be include a substrate (e.g., silicon substrate or insulating substrate). The second portion 2208 may include active and passive devices (e.g., interferometers, superconducting wire detectors, transistors, etc.) and interconnects which include various electrical and/or photonic interconnect structures formed in a dielectric material, such as silicon oxide. The cryo-die 2202 may include various temperature-sensitive components 2220, such as modulators, interferometers, lasers (e.g., laser based single photon sources) and/or superconducting wire detectors formed within the first portion 2206. In some embodiment, one or more temperature-sensitive components 2210 may also be formed in the second portion 2208.

As shown in FIGS. 2A and 2B, the cryo-die 2202 and the secondary die 2204 may be bonded to one another using electrically conductive bonding pads (e.g., copper or copper alloy pads) 2212. The electrically conductive bonding pads 2212 that may extend a certain distance from respective surfaces of the cryo-die 2202 and the secondary die 2204. As such, a gap 2214 is formed between the cryo-die 2202 and the secondary die 2204. The gap 2214 may comprise a vacuum gap if the first hybrid electronic-photonic package 2200a operates in a vacuum chamber.

In other embodiments, such as in the second hybrid electronic-photonic package 2200b of FIG. 2B, an underfill material 2216 may be formed within the gap 2214 between the cryo-die 2202 and the secondary die 2204. The underfill material 2216 may provide structural stability to the second hybrid electronic-photonic package 2200b and may be chosen to have a relatively low thermal conductivity (e.g., a lower thermal conductivity than that of copper). The underfill material 2216 may comprise any suitable polymer material, a carbon material (e.g., diamond or diamond-like carbon), a glass material or a composite material, such as a polymer matrix filled with diamond or glass beads. In one embodiment, the underfill material is a flowable material (e.g., polymer or spin-on glass) which may be flowed between the bonding pads 2212 and then solidified after the cryo-die 2202 is bonded to the secondary die 2204.

FIG. 2C is a vertical cross-sectional view of a third hybrid electronic-photonic package 2200c including a cryo-die 2202 and a secondary die 2204, according to various embodiments. As shown, the third hybrid electronic-photonic package 2200c may include both the underfill material 2216 formed in a portion of a space between the cryo-die 2202 and the secondary die 2204 and a cavity (e.g., a vacuum gap) 2218 formed between surfaces of the cryo-die 2202 and a secondary die 2204. In this regard, the third hybrid electronic-photonic package 2200c may include various blocking features 2220 that are configured to prevent the underfill material 2216 from filling the cavity 2218 when the underfill material 2216 is flowed between the bonded cryo-die 2202 and the secondary die 2204 (or alternatively over the cryo-die 2202 prior to the bonding). In this embodiment, the presence of the cavity 2218 may locally reduce the thermal conduction between the cryo-die 2202 and the secondary die 2204, while the underfill material 2216 may provide structural stability to the third hybrid electronic-photonic package 2200c.

The blocking features 2220 may include any suitable electrically insulating material, such as a polymer material (e.g., a temporary photoresist or a permanent structural polymer) or an inorganic dielectric material, such as silicon oxide, silicon nitride or metal oxide (e.g., alumina). In one embodiment, the blocking features 2220 may physically contact only one of the bonded cryo-die 2202 and the secondary die 2204 to prevent forming a thermal path between the two dies. For example, the blocking features 2220 may be formed only the cryo-die 2202 using photolithography and etching (or photo exposure and development if the blocking features 2220 comprise photoresist), and may have a height that is less than the height of the bonding pads 2212 after the two dies are bonded to each other. Since only a narrow space is left between the top of the blocking features 2220 and the secondary die 2204, the relatively viscous underfill material does not completely fill the cavity 2218 when flowed between the two bonded die or over the surface of the cryo-die before bonding. In one embodiment, if the blocking features 2220 comprise a temporary material, such as photoresist, then the blocking features 2220 may be removed (e.g., by ashing or selective etching) after the underfill material 2116 is solidified.

As shown in FIG. 2C the cavity 2218 may be located near the temperature sensitive component 2210. As such, a flow of heat from the secondary die 2204 to the cryo-die 2202 may be locally reduced near the temperature sensitive element 2210. In this way, thermal isolation of the temperature-sensitive element 2210 may be improved. This embodiment optimizes the thermal isolation and mechanical stability of the third hybrid electronic-photonic package 2200c. Other embodiments may include one or more cavities 2218 located in various places between the cryo-die 2202 and the secondary die 2204. Thus, selective and localized thermal isolation may be achieved that may reduce heat flux in certain temperature-sensitive parts of the assembly.

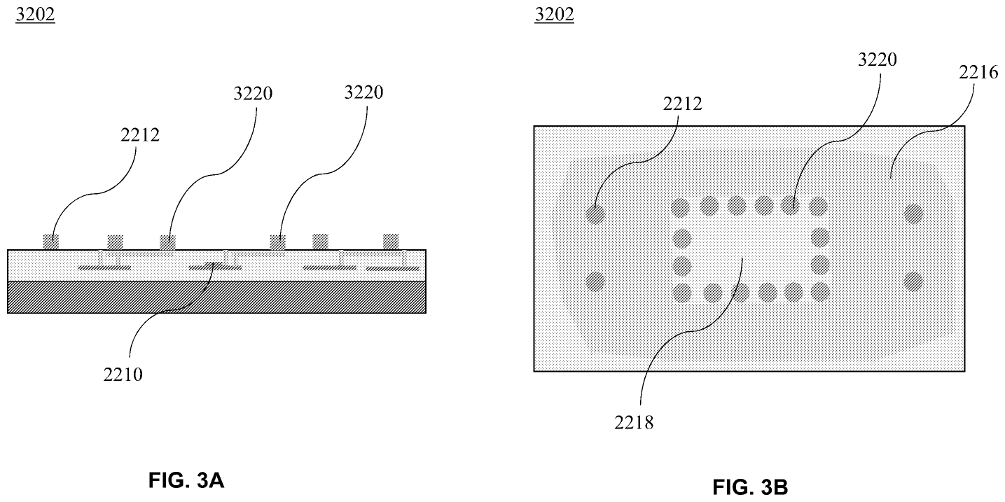

FIG. 3A is a vertical cross-sectional view of a cryo-die 3202 having blocking features 3220 prior to forming the underfill material, and FIG. 3B is a top view of the cryo-die 3202 of FIG. 3A after forming the underfill material, according to various embodiments. In this embodiment, a set of the electrically conductive bonding pads 2212 may serve as blocking features 3220. The blocking features 3220 may be similar to the electrically conductive bonding pads 2212 and may be fabricated during the same deposition and patterning steps as the electrically conductive bonding pads 2212. In one embodiment, the blocking features 3220 may be electrically isolated from other electrically conductive elements. For example, each of the blocking features 3220 may be electrically isolated from the electrically conductive components in the secondary die 2204 after bonding the dies 3202 and 2204 to each other. Alternatively, the blocking features 3220 may comprise active bonding pads which electrically contact electrically conductive components in the secondary die 2204 after bonding the dies 3202 and 2204 to each other.

As shown in FIG. 3B, the blocking features 3220 may formed in a pattern that may form the perimeter of a region that may become a cavity 2218 when underfill material 2216 is deposited. A barrier may be formed by forming the blocking features 3220 to be sufficiently close to one another. A maximum spacing between adjacent ones of the blocking features 3220 may be a function of a viscosity and/or surface tension of the underfill material 2216, such that the underfill material 2216 does not flow between adjacent blocking features 3220 into the cavity 2218 surrounded by the blocking features 3220. In this regard, it may be advantageous to position the blocking features 3220 such that the spacing between adjacent ones of the blocking features 3220 is as large as possible, while maintaining a configuration that may block the underfill material 2216 from entering the cavity 2218. In this way, material costs and manufacturing complexity may be reduced. In this embodiment, the cavity 2218 is shown as a rectangular region in top view. However, the cavity 2218 may have various other geometries in other respective embodiments. For example, the cavity 2218 may have a horizontal cross-sectional shape of a square, a circle, a triangle, an ellipse, a polygon, a channel, etc.

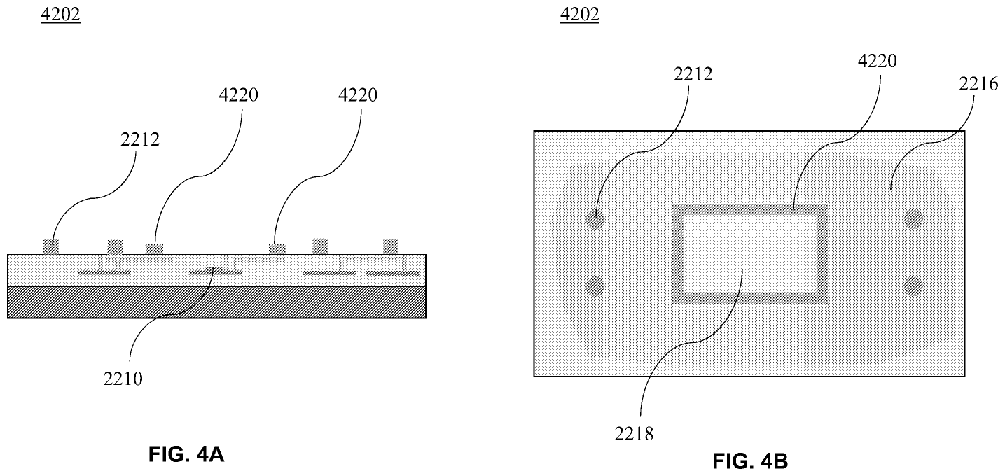

FIG. 4A is a vertical cross-sectional view of a cryo-die 4202 having blocking features 4220 formed as a continuous wall (e.g., a continuous) boundary prior to forming the underfill material, and FIG. 4B is a top view of the cryo-die of FIG. 4A after forming the underfill material, according to various embodiments. As shown in FIG. 4B, the blocking features 4220 may formed as a continuous wall in a pattern that forms the perimeter of a region surrounded by the wall that becomes a cavity 2218 after the underfill material 2216 is deposited. In this example embodiment, the blocking features 4220 may be formed from a polymer, a photoresist, a dielectric film, etc. For example, a blanket layer of a photoresist (not shown) may be deposited over a top surface of the cryo-die 4202. The blanket layer of photoresist may then be patterned using photo exposure and development techniques. For example, exposed portions of a positive photoresist or unexposed portions of a negative photoresist may be removed by a solvent leaving behind the blocking features 4220. In one embodiment, if the blocking features 4220 comprise a temporary material, such as photoresist, then the blocking features 4220 may be removed (e.g., by ashing or selective etching) after the underfill material 1116 is solidified.

Alternatively, a blanket layer of dielectric or polymer (not shown) may be deposited over the over a top surface of the cryo-die 4202. A patterned photoresist may then be formed over the blanket layer of dielectric or polymer using photolithography techniques and an anisotropic etch process may be performed to remove exposed portions of the blanket layer of dielectric or polymer that are not covered by the patterned photoresist. The patterned photoresist may then be removed by a solvent or by ashing. In this example embodiment, the cavity 2218 is shown as a rectangular region. However, the cavity 2218 may have various other geometries in other respective embodiments. For example, the cavity 2218 may have a shape of a square, a circle, a triangle, an ellipse, a polygon, a channel, etc.

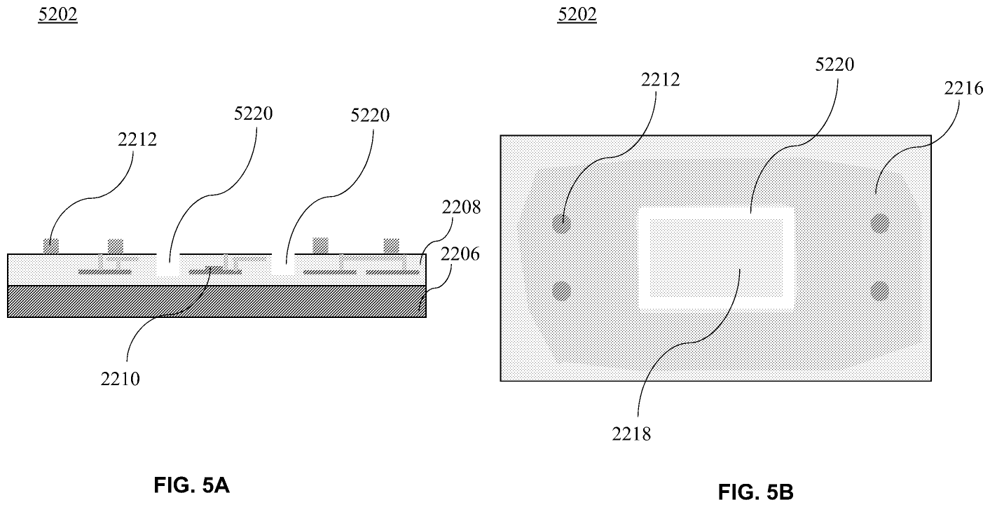

FIG. 5A is a vertical cross-sectional view of a further cryo-die 5202 having blocking features 5220 formed as a continuous trench prior to forming the underfill material, and FIG. 5B is a top view of the cryo-die 5202 of FIG. 5A after forming the underfill material, according to various embodiments. As shown in FIG. 5B, the blocking features 5220 may formed in a pattern that may form the perimeter of a region that becomes the cavity 2218 after underfill material 2216 is deposited. As described above (e.g., see FIG. 2B), the cryo-die 5202 may include the first portion 2206 and the second portion 2208.

As shown in FIG. 5A, the blocking features 5220 may be formed as a trench in a top surface of the second portion 2208. For example, a patterned photoresist (not shown) may be formed over a top surface of the cryo-die 5202 and an etching process may be performed to form the trenches that serve as the blocking features 5220. As shown in FIG. 5A, the trenches may have straight sidewalls that may be generated by performing an anisotropic etch. Alternatively, the trench may have various other shapes. For example, the trench may have a shape including an undercut region (not shown) by performing an isotropic etch. The blocking features 5220, formed as a trench in the embodiments of FIGS. 5A and 5B may act to block the flow of the underfill material 2216 by allowing a portion of the underfill material 2216 to flow into the trench. The portion that flows into the trench may correspond to a volume of underfill material 2216 that might otherwise flow into the cavity 2218 without the presence of the trench.

The underfill material 2216 may be flowed over the cryo-die 5202 before or after bonding the cryo-die 5202 to the secondary die 2204 in the embodiments of FIGS. 3B, 4B and 5B. In these embodiments, if the at least one blocking feature comprises a sacrificial material (e.g., photoresist, etc.), then the at least one blocking feature may be selectively removed (e.g., by ashing or selective etching) after solidifying the underfill material 2216.

Each of the embodiments of FIGS. 2A to 5B are based on a flip-chip or chip-on-chip assembly protocol that uses a vacuum gap and/or a low thermal conductivity underfill material to provide thermal isolation to the cryo-die 2202, 3202, 4202, 5202. Placement of blocking features 2220, 3220, 4220, 5220 (e.g., pillars, walls, trenches, etc.) allow formation of cavities 2218 after deposition of the underfill material 2216 which creates thermally isolated regions of the cryo-die. In alternative embodiments, the temperature sensitive cryo-die regions may be separated into a stand-alone die or sub-assembly, which may have no direct contact with the secondary die 2204. However, adding such additional physical separations may pose challenges for efficient electrical connectivity between the cryo-die 2202, 3202, 4202, 5202 and the secondary die 2204. In this regard, a compromise between electrical connection and thermal isolation may be optimized in certain embodiments.

The disclosed embodiments may have advantages over existing systems by providing significant reduction of heat flux and thermal cooling requirements for cooling of the temperature sensitive elements 2210. In this regard, the thermally isolated regions (e.g., cavity 2218 or vacuum gap 2214) may provide enhanced thermal isolation to temperature-sensitive elements 2210. The various embodiments may be fabricated using standard semiconductor assembly and test (OSAT) protocols. As such, little or no modification of the layers or structures in the cryo-die 2202, 3202, 4202, 5202 and secondary dies 2204 may be needed, making the disclosed embodiments compatible with existing wafer fabrication processes. Selectively patterned regions of integrated cavities 2218 allow for localized control of the heat flux in the same assembly, not requiring altering or add complexity to the design or assembly flow. As such, temperature sensitive elements 2210 may be thermally isolated from the secondary die 2204 during the standard flip-chip assembly process.

The following are example embodiments:
Example 1: A hybrid electronic-photonic package, comprising: a photonic die comprising photonic components; an electronic die bonded to the photonic die; and at least one of a cavity and an underfill material having a lower thermal conductivity than materials of the photonic die and the electronic die located between the photonic die and the electronic die.
Example 2: The hybrid electronic-photonic package of Example 1, wherein the photonic die comprises a cryo-die configured to operate between 1 and 4.2 degrees Kelvin.
Example 3: The hybrid electronic-photonic package of Example 1 or Example 2, wherein the at least one of the cavity and the underfill material comprises the cavity which functions as a vacuum gap.
Example 4: The hybrid electronic-photonic package of any one of Examples 1-3, wherein the at least one of the cavity and the underfill material comprises the underfill material.
Example 5: The hybrid electronic-photonic package of any one of Examples 1-4, wherein the underfill material comprises at least one of a polymer, a carbon or a glass material.
Example 6: The hybrid electronic-photonic package of any one of Examples 1-5, wherein the underfill material comprises a composite material comprising a polymer matrix containing glass or diamond fill.
Example 7: The hybrid electronic-photonic package of any one of Examples 1-6, wherein the at least one of the cavity and the underfill material comprises the cavity surrounded by the underfill material.
Example 8: The hybrid electronic-photonic package of any one of Examples 1-7, wherein the cavity is located adjacent to a temperature sensitive cryo component located in the cryo-die.
Example 9: The hybrid electronic-photonic package of any one of Examples 1-8, further comprising at least one blocking feature located between the cavity and the underfill material.
Example 10: The hybrid electronic-photonic package of any one of Examples 1-9, wherein the at least one blocking feature comprises a plurality of bonding pads surrounding the cavity, a dielectric material wall surrounding the cavity, or a trench surrounding the cavity.
Example 11: A method of making a hybrid electronic-photonic package, comprising: providing a photonic die comprising photonic components; providing an electronic die; and bonding the electronic die to the photonic die such that at least one of a cavity and an underfill material having a lower thermal conductivity than materials of the photonic die and the electronic die is located between the photonic die and the electronic die.
Example 12: The method of Example 11, wherein the photonic die comprises a cryo-die configured to operate between 1 and 4.2 degrees Kelvin.
Example 13: The method of Example 11 or Example 12, wherein the at least one of the cavity and the underfill material comprises the cavity which functions as a vacuum gap.
Example 14: The method of any one of Examples 11-13, wherein the at least one of the cavity and the underfill material comprises the underfill material.
Example 15: The method of any one of Examples 11-14, wherein the underfill material comprises at least one of a polymer material, a carbon material, a glass material, or a composite material comprising a polymer matrix containing glass or diamond fill.
Example 16: The method of any one of Examples 11-15, wherein the at least one of the cavity and the underfill material comprises the cavity surrounded by the underfill material, and wherein the cavity is located adjacent to a temperature sensitive cryo component located in the cryo-die.
Example 17: The method of any one of Examples 11-16, further comprising: flowing the underfill material over the cryo-die before or after the bonding; and solidifying the underfill material.
Example 18: The method of any one of Examples 11-17, further comprising forming at least one blocking feature around the cavity prior to flowing the underfill material, wherein the at least one blocking feature blocks the underfill material from flowing into the cavity.
Example 19: The method of any one of Examples 11-18, wherein the at least one blocking feature comprises a plurality of bonding pads surrounding the cavity, a dielectric material wall surrounding the cavity, or a trench surrounding the cavity.
Example 20: The method of any one of Examples 11-19, further comprising selectively removing the at least one blocking feature after solidifying the underfill material.

In addition to quantum computing and cryogenic electronics applications, the assemblies of various disclosed embodiments may be used in datacom/telecom systems, integrated in-package optics systems, as well as artificial intelligence systems which rely on co-integration of photonics with advanced CMOS. In this regard, heat removal and thermal control over localized regions of the photonic die elements may provide additional design flexibility for co-integration of complex ASIC circuits that generate heat with the photonic integrated circuits that typically include temperature sensitive integrated components, such as detectors (e.g., superconducting detectors), lasers, modulators, single-photon sources, etc.

The terminology used in the description of the various described embodiments herein is for the purpose of describing particular embodiments only and is not intended to be limiting. As used in the description of the various described embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A hybrid electronic-photonic package, comprising:
a photonic die comprising photonic components;
an electronic die bonded to the photonic die; and
at least one of a cavity and an underfill material having a lower thermal conductivity than materials of the photonic die and the electronic die located between the photonic die and the electronic die.

2. The hybrid electronic-photonic package of claim 1, wherein the photonic die comprises a cryo-die configured to operate between 1 and 4.2 degrees Kelvin.

3. The hybrid electronic-photonic package of claim 2, wherein the at least one of the cavity and the underfill material comprises the cavity which functions as a vacuum gap.

4. The hybrid electronic-photonic package of claim 2, wherein the at least one of the cavity and the underfill material comprises the underfill material.

5. The hybrid electronic-photonic package of claim 4, wherein the underfill material comprises at least one of a polymer, a carbon or a glass material.

6. The hybrid electronic-photonic package of claim 4, wherein the underfill material comprises a composite material comprising a polymer matrix containing glass or diamond fill.

7. The hybrid electronic-photonic package of claim 2, wherein the at least one of the cavity and the underfill material comprises the cavity surrounded by the underfill material.

8. The hybrid electronic-photonic package of claim 7, wherein the cavity is located adjacent to a temperature sensitive cryo component located in the cryo-die.

9. The hybrid electronic-photonic package of claim 8, further comprising at least one blocking feature located between the cavity and the underfill material.

10. The hybrid electronic-photonic package of claim 9, wherein the at least one blocking feature comprises a plurality of bonding pads surrounding the cavity, a dielectric material wall surrounding the cavity, or a trench surrounding the cavity.

11. A method of making a hybrid electronic-photonic package, comprising:
providing a photonic die comprising photonic components;
providing an electronic die; and
bonding the electronic die to the photonic die such that at least one of a cavity and an underfill material having a lower thermal conductivity than materials of the photonic die and the electronic die is located between the photonic die and the electronic die.

12. The method claim 11, wherein the photonic die comprises a cryo-die configured to operate between 1 and 4.2 degrees Kelvin.

13. The method claim 12, wherein the at least one of the cavity and the underfill material comprises the cavity which functions as a vacuum gap.

14. The method claim 12, wherein the at least one of the cavity and the underfill material comprises the underfill material.

15. The method claim 14, wherein the underfill material comprises at least one of a polymer material, a carbon material, a glass material, or a composite material comprising a polymer matrix containing glass or diamond fill.

16. The method claim 12, wherein the at least one of the cavity and the underfill material comprises the cavity surrounded by the underfill material, and wherein the cavity is located adjacent to a temperature sensitive cryo component located in the cryo-die.

17. The method claim 16, further comprising:
flowing the underfill material over the cryo-die before or after the bonding; and
solidifying the underfill material.

18. The method claim 17, further comprising forming at least one blocking feature around the cavity prior to flowing the underfill material, wherein the at least one blocking feature blocks the underfill material from flowing into the cavity.

19. The method claim 18, wherein the at least one blocking feature comprises a plurality of bonding pads surrounding the cavity, a dielectric material wall surrounding the cavity, or a trench surrounding the cavity.

20. The method claim 18, further comprising selectively removing the at least one blocking feature after solidifying the underfill material.
